(19) United States
(12) Patent Application Publication
(10) Pub. No.: US 2025/0004211 A1
(43) Pub. Date: Jan. 2, 2025

(54) ERROR CORRECTION AND RECOVERY IN OPTICAL COMMUNICATION SYSTEMS WITH LOW-POWER OPTICAL SOURCE DEVICES

(71) Applicant: Marvell Asia Pte Ltd, Singapore (SG)

(72) Inventors: Michael Lewis TAKEFMAN, Nepean (CA); Jamal RIANI, Fremont, CA (US); Michael DUCKERING, Kanata (CA)

(21) Appl. No.: 18/732,569

(22) Filed: Jun. 3, 2024

Related U.S. Application Data
(60) Provisional application No. 63/470,428, filed on Jun. 1, 2023.

(51) Int. Cl. G02B 6/42; H04B 10/50

(52) U.S. Cl. CPC G02B 6/4203; H04B 10/502

(57) ABSTRACT

A first communication device receives a set of bits for transmission over a plurality of lanes of an optical communication link. The optical communication link includes a larger number of lanes than a number of lanes needed to support transmission at a particular clock rate to provide a maximum speed supported by the optical communication link. The first communication device multiplexes the set of data bits for transmission over respective lanes and transmits the multiplexed set of bits over the lanes to a second communication device. The first communication device uses the larger number of lanes for transmission of error correction code bits in addition to the set of bits at the particular clock rate over the plurality of lanes at the maximum speed supported by the optical communication link and/or uses the larger number of lanes to provide one or more redundancy lanes in the optical communication link.

### CROSS REFERENCES TO RELATED APPLICATIONS

This application claims the benefit of U.S. Provisional Patent Application No. 63/470,428, entitled “Large Channel Count Active Optical Cable Forward Error Correction Improvements and Error/Redundancy Control,” filed on Jun. 1, 2023, the disclosure of which is hereby expressly incorporated herein by reference in its entirety.

### FIELD OF TECHNOLOGY

The present disclosure relates generally to transmission of data via optical medium, and more particularly to error correction and fault recovery in transmission of data via optical cables using low power optical source devices.

### BACKGROUND

An active optical cable (AOC) is a point-to-point link between two electronic devices (e.g., switches, servers, etc.) where fiber optics is used as a physical medium to communicate between devices. Traditionally an AOC uses one or more lasers as a light source and has a relatively small number of fiber pairs. Some systems use Light Emitting Diodes (LED) rather than lasers to save power. Although the LED typically transmits data at a lower bit-rate as compared to a laser, power consumption of the LED is significantly less than the ratio of their respective bandwidths. Accordingly, an optical cable built with a very large count of fiber pairs for transmission using LEDs offers power savings as compared to optical systems that use lasers as optical source devices for transmission of data over an optical communication link.

### SUMMARY

In an embodiment, a method for communication over an optical communication link is provided. The method includes: receiving, at a first communication device, a set of bits for transmission over a plurality of lanes of the optical communication link, respective lanes among the plurality of lanes comprising respective fibers driven by respective light emitting diodes (LEDs), wherein the optical communication link includes a larger number of lanes than a number of lanes needed to support transmission at a particular clock rate to provide a maximum speed supported by the optical communication link; multiplexing, by the first communication device, the set of data bits for transmission over respective lanes among the plurality of lanes, including one or both of i) using the larger number of lanes for transmission of error correction code bits in addition to the set of bits at the particular clock rate over the plurality of lanes at the maximum speed supported by the optical communication link and ii) using the larger number of lanes to provide one or more redundancy lanes in the optical communication link; and transmitting, by the first communication device, the multiplexed set of bits over the plurality of lanes of the optical communication link to a second communication device.

In another embodiment, a first communication device is provided. The first communication device comprises a transceiver including: a receiver configured to receive a set of bits for transmission over a plurality of lanes of an optical communication link, respective lanes among the plurality of lanes comprising respective fibers driven by respective light emitting diodes (LEDs), wherein the optical communication link includes a larger number of lanes than a number of lanes needed to support transmission at a particular clock rate to provide a maximum speed supported by the optical communication link; one or more multiplexers configured to multiplex the set of data bits for transmission over respective lanes among the plurality of lanes, including one or both of i) using the larger number of lanes for transmission of error correction code bits in addition to the set of bits at the particular clock rate over the plurality of lanes at the maximum speed supported by the optical communication link and ii) using the larger number of lanes to provide one or more redundancy lanes in the optical communication link; and a transmitter configured to transmit the multiplexed set of bits over the plurality of lanes of the optical communication link to a second communication device.

### BRIEF DESCRIPTION OF THE DRAWINGS

FIG. 1 is a simplified diagram of an example system in which an optical cable has a greater number of lanes than needed to support a maximum speed of a communication link provided via the optical cable, according to an embodiment.

FIG. 2A is a block diagram of a portion of an example transmitter device used in the system of FIG. 1, according to an embodiment.

FIG. 2B is a block diagram of a portion of an example receiver device used to receive signals transmitted by the transmitter device of FIG. 2A, according to an embodiment.

FIG. 3A is a block diagram of a portion of an example transmitter device used in the system of FIG. 1, according to another embodiment.

FIG. 3B is a block diagram of a portion of an example receiver device used to receive signals transmitted by the transmitter device of FIG. 3A, according to an embodiment.

FIG. 4 is a block diagram of example transmit circuitry of the transmitter device of FIG. 3A, according to an embodiment.

FIG. 5A is a block diagram of a portion of an example transmitter device used in the system of FIG. 1, according to yet another embodiment.

FIG. 5B is a block diagram of a portion of an example receiver device used to receive signals transmitted by the transmitter device of FIG. 5A, according to an embodiment.

FIG. 6 illustrates an example re-mapping function used by the transmitter device of FIG. 5A, according to an embodiment.

FIG. 7 is a block diagram of an example redundancy controller used in the system of FIG. 1, according to an embodiment.

FIG. 8 is a block diagram of an example redundancy controller used in the system of FIG. 1, according to another embodiment.

FIG. 9 is a flow diagram of an example method for communication over an optical cable communication link, according to an embodiment.

### DETAILED DESCRIPTION

As discussed above, optical communication systems that use low power semiconductor devices, such as light emitting diodes, are designed with a larger number of lanes or fiber pairs as compared to optical communication systems that use lasers. In embodiments described below, an optical communication system utilizes an optical communication link that includes a number of lanes that is greater than the number of lanes needed to transmit data at a particular clock rate at a maximum link speed supported by the optical communication link. In an embodiment, the optical system utilizes the additional lanes for additional encoding of the data without increasing a per-lane transmission speed. Additionally or alternatively, the optical system utilizes the additional lanes as redundant lanes that are used to repair the optical communication link in the presence of one or more dead or faulty lanes in the optical communication link. As discussed in more detail below, in various embodiments, including the additional lanes in the optical communication link and using the additional lanes for additional encoding and/or redundancy improves the resilience and reliability of the optical communication link, in at least some embodiments. For example, in at least some embodiments, the additional lanes allow the optical communication system to implement hitless recovery to repair the optical communication link in the presence of a faulty or dead lane and/or to improve bit error rate of the optical communication link under burst error conditions without losing lock and having to re-initialize the optical communication link. Because laser devices consume significantly greater power as compared to lower power semiconductor devices, such as light emitting diodes, as the optical source devices for transmission of data over an optical communication link, typical optical communication links that utilize lasers for data transmission do not include such additional lanes, and typical optical communication devices that utilize lasers for data transmission are not configured to utilize additional data lanes. As a result, hitless recovery is typically not possible in optical communication systems that utilizes lasers as the optical source devices for transmission of data over an optical communication link.

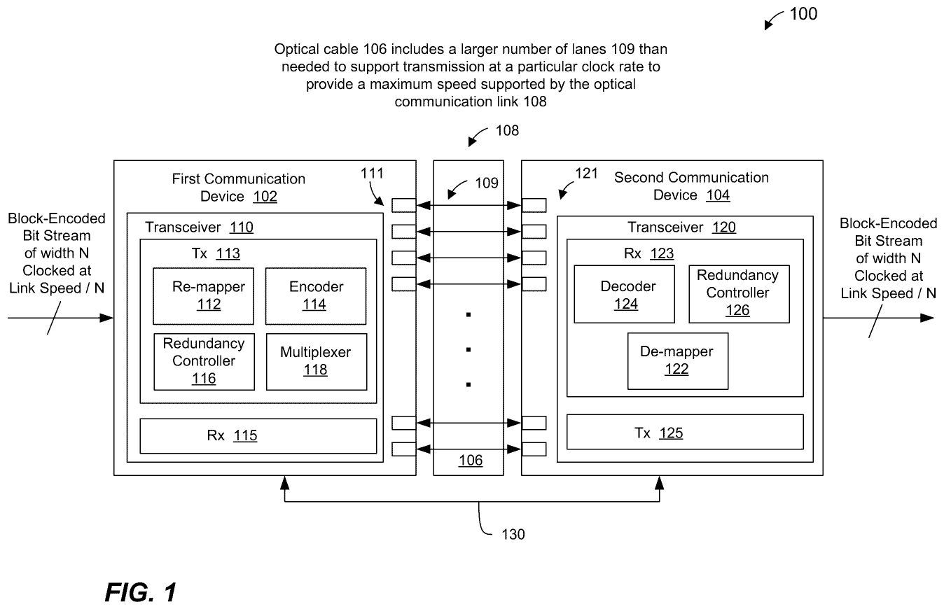

FIG. 1 is a simplified diagram of an example system 100 in which an optical cable includes a greater number of lanes than needed to support a maximum speed of a communication link provided via the optical cable, according to an embodiment. The system 100 includes a first communication device 102 coupled to a second communication device 104 via an optical cable 106. In an embodiment, the first communication device 102, the second communication device 104 and the optical cable 106 form an active optical cable used to communicatively couple host devices, such as switches or end-point host devices. In another embodiment, the first communication device 102 and the second communication device 104 are parts of host devices coupled via the optical cable 106. For example, a first switch device includes or otherwise implements the first communication device 102 and a second switch device includes or otherwise implements the second communication device 104, in an embodiment. The first communication device 102 includes a transceiver 110 which, in turn, includes a transmitter 113 and a receiver 115, in the illustrated embodiment. The second communication device 104 includes a transceiver 120 which, in turn, includes a receiver 123 and a transmitter 125, in the illustrated embodiment.

In an embodiment, the optical cable 106 provides an optical communication link 108 comprising a plurality of channels (sometimes also referred to herein as “lanes”) 109. Respective lanes 109 comprise respective fibers or respective fiber pairs for transmission of signals in the optical cable 106. The first communication device 102 includes a plurality of optical source devices 111 coupled to the plurality of lanes 109. The optical source devices 111 are relatively lower power devices as compared to lasers, in an embodiment. In an embodiment, the optical source devices 111 comprise light emitting diodes (LEDs). In other embodiments, other suitable optical source device that are lower in power as compared to lasers are used. The second communication device 104 includes a plurality of optical detector devices 121 coupled to the plurality of lanes 109. In an embodiment, the optical detector devices 121 comprise photodiodes. In other embodiments, other suitable optical detector devices are used. In an embodiment, each optical source device 111 is configured to transmit the light signals at a bit-rate that is relatively lower as compared to a bit-rate that can be transmitted by a laser source device. However, power consumption of each optical source device 111 is significantly less than the ratio of the bandwidth optical source device 111 to the bandwidth of a typical laser source device, in at least some embodiments. Accordingly, the first communication device 102 includes a significantly larger number of optical source devices 111 as compared to a typical communication device that utilizes lasers for data transmission while still operating at a lower power as compared to the typical optical transmitter that utilizes lasers. Consequently, the optical cable 106 includes a corresponding greater number of lanes 109 for data transmission as compared to a number of data lanes in an optical cable used with a typical communication device that utilizes lasers for data transmission.

In an embodiment, the first communication device 102 is configured to use the larger number of optical source devices 111 and lanes 109 to transmit data that includes an expanded number of bits due to additional encoding of the data by the transmitter 113 of the first communication device 102. The use of additional optical source devices 111 and lanes 109 for transmission of the additionally encoded data allows the additionally encoded data to be transmitted without increasing the clock rate relative to the clock rate used for transmission of data without the additional encoding while still supporting the maximum speed of the communication link 108. The use of additional optical source devices 111 and lanes 109 for transmission of the additionally encoded data thus simplifies the design of the transceiver 110 as compared to systems in which lanes to accommodate additional encoding are not provided, in at least some embodiments. Additionally or alternatively, the first communication device 102 is configured to use the larger number of optical source devices 111 and lanes 109 by using one or more lanes 109 as redundancy lanes. For example, the first communication device 102 is configured to determine that a fault or hard failure has occurred on a particular lane 109 that is driven by a particular diode 111 of the first communication device 102 and received by a particular diode 121 of the second communication device 104. In an embodiment, as explained in more detail below, the first communication device 102 is configured to determine that the fault or hard failure has occurred on a lane 109 in response receiving an indication from the second communication device 104 that a dead or silent lane was detected by the receiver 121 of the second communication device 104.

The first communication device 102 is configured to transfer transmission of data from the particular lane 109 to a redundant lane 109 in response to determining that a fault or hard failure has occurred on the particular lane 109, in an embodiment. The redundant lane 109 is driven by a diode 111 different from the diode 111 that drives the faulty lane 109 and is received by a diode 121 different from the diode 121 that receives the faulty lane 109, in an embodiment. In an embodiment, the first communication device 102 is configured to determine that a fault has occurred and to transfer transmission from the faulty lane onto the redundant lane before the link is determined to be down by a higher-layer processing unit (e.g., a media access controller (MAC)) included in or coupled to the receiver 123 of the second communication device 104, for example due to high bit error rate on the communication link 108 as determined by the higher-layer processing unit included in or coupled to the receiver 123 of the second communication device 104. In this case, transfer of transmission from the faulty lane onto the redundant lane allows for hitless recovery of the communication link 108 where the communication link 108 is repaired in the background without losing lock and having to reinitialize the communication link 108.

The first communication device 102 is configured to receive a deserialized serial bit stream for transmission over the optical cable 106. The deserialized bit stream includes N bits transmitted by a SERDES at a host clock rate Cₕₒₛₜ. In an embodiment N is 128 bits and the clock rate Cₕₒₛₜ is 880 MHz, for example. The first communication device 102 includes a retimer or a gearbox that is generally configured to convert a data stream of a first bit width clock at a first clock rate to a data stream of a second bit width clocked at a second clock rate, in an embodiment. In an embodiment, the retimer or gearbox is configured to output N bits onto D LED lanes clocked at a line clock rate Cₗᵢₙₑ derived from the host clock rate Cₕₒₛₜ. The number D of lanes and the derived clock Cₗᵢₙₑ are determined such that the data stream is transmitted at an overall bit rate that is equal to or greater than a link speed of the communication link 108. For example, in an embodiment in which the guaranteed useful transmission rate on the communication link 108 is 100 GHz, the number of lanes is 32 and the clock rate Cₗᵢₙₑ is 3.52 GHz. In this embodiment, the clock rate Cₗᵢₙₑ is equal to the clock rate Cₕₒₛₜ multiplied by 4, and the overall speed of the communication link 108 is 112.64 GHz, which is sufficient to guarantee the 100 GHz transmission speed on the optical communication link 108 while allowing for transmission of overhead bits such as Ethernet FEC bits.

In an embodiment, the transmitter 113 of the first communication device 102 includes a re-mapper 112, an encoder 114, a redundancy controller 116 and a multiplexer 118. The multiplexer 118 is configured to multiplex bits of a data stream for transmission over respective lanes 109 of the optical cable 106. As described in more detail below, the re-mapper 112 is configured to interleave bits of an encoded data stream received for transmission by the transmitter 113 to better distribute the bits among the lanes 109, the encoder 114 is configured to further encode the encoded data stream, and the redundancy controller 116 is configured to control transfer of transmission of data from a dead or faulty lane 109 onto a redundant lane 109, in various embodiments. As also explained in more detail below, operations performed by the re-mapper 112, the encoder 114, and the redundancy controller 116 improve resilience to burst errors on the optical communication link 108 and/or enable repair of dead lanes 109 in the optical communication link 108, in various embodiments. In some embodiments, the transmitter 113 omits one or more of the re-mapper 112, the encoder 114, and the redundancy controller 116.

The receiver 123 of the second communication device 104 includes a de-mapper 122, a decoder 124, and a redundancy controller 126, in an embodiment. The de-mapper 122 is configured to reverse the interleaving performed by the re-mapper 112. The decoder 124 is configured to decode the data stream encoded by the encoder 114. The redundancy controller 126 is configured to detect a faulty or dead lane 109 and to coordinate transfer of transmission of data from the faulty or dead lane 109 to a redundant lane 109 with the redundancy controller 116, in an embodiment. In some embodiments, the receiver 123 omits one or more of the de-mapper 122, the decoder 124, and the redundancy controller 126. In an embodiment, the receiver 115 of the first communication device 102 is generally the same as the receiver 123 of the second communication device 104. Similarly, the transmitter 125 of the second communication device 104 is generally the same as the transmitter 113 of the first communication device 102, in an embodiment.

In an embodiment, the data stream received by the first communication device 102 is encoded using a particular coding scheme. For example, the data stream is encoded using the Reed Solomon (RS) block encoding scheme. In an embodiment, the data stream is encoded using Ethernet RS (544, 514) block encoding scheme. In this scheme, a Reed Solomon block code is used in which 514 10-bit data symbols are augmented with 30 10-bit check symbols to produce a 544 symbol code word. This RS code can correct 15 errored symbols. Because the data stream is gearboxed and multiplexed onto a fewer number of data lanes, transmission of the data is not resilient to burst errors in at least some situations. For example, direct distribution of bits in the data stream among the lanes 109 results in a distribution in which bits in multiple symbols of the RS code are mapped on the same data lane 109. As a result, a burst error on the data lane 109 is distributed among multiple symbols of the RS code and is thus not correctable by the RS code in at least some situations.

As discussed in more detail below, in an embodiment, the re-mapper 112 of the first communication device 102 interleaves or re-maps bits in the data stream such that the bits are distributed among the lanes 109 in a manner that maximizes mapping of bits from a same symbol of the RS code onto same lanes 109, thus minimizing distribution of burst errors among multiple symbols of the RS code. For example, the re-mapper 112 interleaves or re-maps the bits to ensure that bits of a same symbol of the RS code are mapped maximally or entirely onto a same lane 109. In this case, a burst error on a particular lane 109 affects fewer symbols of the RS code as compared to a system in which such re-mapping is not performed. Thus, such re-mapping makes transmission of the data stream more resilient to burst errors and more correctable by the RS code, in an embodiment. The data stream is then de-mapped by the de-mapper 122 of the second communication device 104 to restore the order of the data bits prior to providing the data stream for decoding according to the Ethernet decoding scheme, in an embodiment.

Additionally or alternatively, in some embodiments, the encoder 114 of the first communication device 102 further encodes the data stream prior to transmission of the data stream. In an embodiment, the encoder 114 is a block code encoder configured to further encode the data stream using a block code, such as an RS code. In another embodiment, the encoder 114 is configured to use a code different from a block code. For example, the encoder 114 is configured to encode the data stream using a Hamming code, in an embodiment. In another example, the encoder 114 is configured to encode the data stream by adding cyclic redundancy check (CRC) bits generated based on the data bits. The data stream received by the second communication device 104 is then decoded by the decoder 124 of the second communication device 104. The decoder 124 can thus correct and detect one or more errors in the received data stream prior to providing the data stream for decoding according to the Ethernet decoding scheme, in an embodiment. In at least some embodiments, further encoding the data stream makes transmission of the data more resilient to burst errors due to the detection and correction of some errors at the second communication device 104 before the corrected bit stream is provided for decoding according to the Ethernet decoding scheme.

In an embodiment, the redundancy controller 116 of the first communication device 102 and the redundancy controller 126 of the second communication device 104 are configured to cooperate with each other to implement redundant transmission of data from the first communication device 102 to the second communication device 104. In an embodiment, the redundancy controller 126 of the second communication device 104 is configured to detect a fault on a lane 109 and to provide an indication of the faulty lane 109 to the first communication device 102. In an embodiment, the redundancy controller 126 of the second communication device 104 provides an indication of the faulty lane 109 to the first communication device 102 via a sideband channel 130 provided between the first communication device 102 and the second communication device 104. Further, the redundancy controller 126 of the second communication device 104 is configured to, in response to detecting the fault on the lane 109, reconfigured the receiver 123 of the second communication device 104 to transfer reception of data from the faulty lane 109 to a redundant lane 109. The redundancy controller 116 of the first communication device 102 is configured to receive the indication of the faulty lane from the second communication device 104, and to transfer transmission of data from the faulty lane 109 to the redundant lane 109. In an embodiment, the second communication device 104 is configured to detect the fault prior to loss of lock between the first communication device 102 and the second communication device 104 due to the fault. For example, the second communication device 104 is configured to monitor the lanes 109 using “stuck on” detectors configured to detect a fault in response to detecting that a bit stream received from a particular lane 109 is stuck at bit value of zero or one for a predetermined period of time. In other embodiments, other suitable detection mechanisms are used.

As described in more detail below, in various embodiments, one or more of i) the use of additional lanes for transmission of data further encoded by the first communication device 102, ii) the use of additional lanes 109 to provide redundancy, iii) fast detection of faulty lanes 109 at the second communication device 104, iv) the use of a sideband channel for transmission of indications of faulty lanes from the second communication device 104 to the first communication device 102, v) efficient transfer of transmission of data from a faulty lane 109 to a redundant lane 109, etc. allows the communication system 100 to perform transmission of data in a manner resilient to burst errors and/or implement hitless recovery from lane faults.

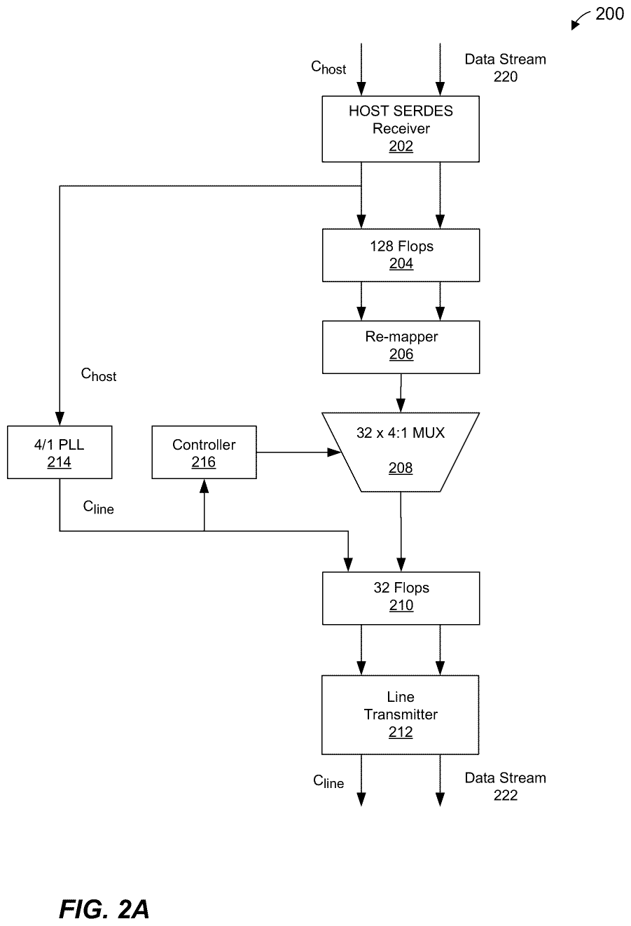

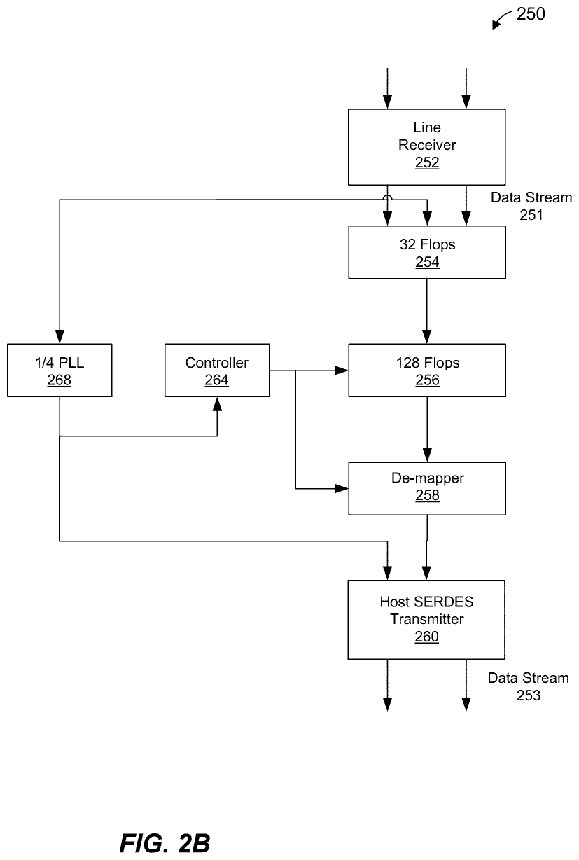

FIG. 2A is a block diagram of a portion of an example transmitter device 200, according to an embodiment. The transmitter device 200 corresponds to, or is included in, the optical first communication device 102 of the communication system 100 of FIG. 1, and for illustrative purposes the transmitter device 200 is described with reference to FIG. 1. However, the transmitter device 200 is used in communication systems different from the communication system of FIG. 1, in some embodiments. Similarly, the optical first communication device 102 of the communication system 100 of FIG. 1 is different from the transmitter device 200, in some embodiments.

The transmitter device 200 includes a SERDES receiver block 202, a first set of flip-flops 204, a re-mapper 206, a plurality of multiplexers 208, a second set of flip-flops 210 and a line transmitter 212. The transmitter device 200 also includes a phase lock loop (PLL) 214 and a controller 216. The transmitter device 200 is configured to receive a data stream 220 for transmission over a communication link (e.g., the optical communication link 108 of FIG. 1) that supports a certain maximum link speed, such as 100 GHz. The data stream 220 corresponds to a serial data stream that is converted by a host SERDES to a parallel data stream of width N at a clock rate Cₕₒₛₜ, where the clock rate Cₕₒₛₜ is equal to or greater than the maximum link speed divided by N. In an embodiment, the width N of the data stream 220 is 128 bits, and the clock rate Cₕₒₛₜ is 880 MHz. In other embodiments, other suitable data stream widths and/or other suitable clock rates are used. The transmitter device 200 is configured to gearbox the received data stream 220 to a data stream 222 of width M clocked at a clock rate Cₗᵢₙₑ that is proportional to the clock rate Cₕₒₛₜ. The first set of flip-flops 204, the re-mapper 206, the plurality of multiplexers 208, the second set of flip-flops 210, the PLL 214 and the controller 216 are configured to implement the gearbox functionality of the transmitter device 200, in an embodiment.

The SERDES receiver block 202 is configured to receive N bits of data from the host SERDES device and to store the N bits in the first set of flip-flops 204. The first set of flip-flops 204 includes 128 flip-flops to store 128 bits of the data stream 220, in the illustrated embodiment. In an embodiment, the data stream 220 received by the SERDES receiver block 202 is an encoded data stream, encoded according to a block code that includes a plurality of symbols forming a codeword of the block code. For example, the data stream 220 is encoded by the Ethernet RS (544, 514) code. The PLL 214 is configured to receive a clock signal corresponding to the clock rate Cₕₒₛₜ from the host SERDES device and to derive a clock signal corresponding to the line clock rate Cₗᵢₙₑ that is proportional to the clock rate Cₕₒₛₜ of the host device. In some embodiments, the clock signal received by the PLL 214 is noisy, and the PLL 214 is further configured to clean up the clock signal to generate a clean clock signal corresponding to the line clock rate Cₗᵢₙₑ. In an embodiment, the clock rate Cₗᵢₙₑ is obtained from the clock rate Cₕₒₛₜ by multiplying Cₕₒₛₜ by a factor of N/M (e.g., 4 in the illustrated embodiment). Accordingly, the PLL 214 is configured to generate a clock signal that is a multiple of the clock signal from the host SERDES device by a factor of four, in the illustrated embodiment.

The re-mapper 206 remaps the bits output from the first set of flip-flops 204 to maximize mapping of bits from a same symbol of the block code onto same lanes 109, thus minimizing distribution of burst errors among multiple symbols of the block code. For example, the re-mapper 206 interleaves or re-maps the bits to ensure that bits of a same symbol of the RS code are mapped maximally or entirely onto a same lane 109. In this case, a burst error on a particular lane 109 affects fewer symbols of the RS code as compared to a system in which such re-mapping is not performed. Thus, such re-mapping makes transmission of the data stream more resilient to burst errors and more correctable by the RS code, in an embodiment. In an embodiment, the re-mapper 206 is configured to remap the bits according to the following mapping function:
for i in range (8):
   for j in range (4):
      for k in range (4):

d_out[k+j*32+i*4]=d_in[k+4*j+16*i] Equation 1

The remapping function of Equation 1 maps 128 bits onto 32 data lanes such that, in most cases, four consecutive bits of a same symbol of the Ethernet RS (544, 514) code are mapped onto a same data lane. In other embodiments, other suitable remapping functions are used. The bits remapped by the re-mapper 206 are provided to the set of multiplexers 208. The set of multiplexers 208 include 32 4:1 multiplexers, in the illustrated embodiment. The multiplexers 208 are controlled by the controller 216 at the clock rate Cₗᵢₙₑ. Each of the multiplexers 208 is configured to output a bit every clock cycle at the clock rate Cₗᵢₙₑ. The outputs of the multiplexers 208 are stored in the second set of flip-flops 210. The second set of flip-flops 210 includes 32 flip-flops, in the illustrated embodiment. The second set of flip-flops 210 is controlled by the controller 216 to output 32 signals per clock cycle at the clock rate Cₗᵢₙₑ. The 32 signals drive respective LEDs of the transmitter device 200. The LEDs convert the signals into light signals and output respective ones of the light signals onto respective ones of the 32 data lanes of the communication link 108 for transmission to the second communication device 104, in an embodiment.

FIG. 2B is a block diagram of an example receiver 250 configured to receive signals transmitted by the transmitter 200 of FIG. 2A, according to an embodiment. The receiver device 250 corresponds to, or is included in, the optical second communication device 104 of the communication system 100 of FIG. 1, and for illustrative purposes the receiver device 250 is described with reference to FIG. 1. However, the receiver device 250 is used in communication systems different from the communication system of FIG. 1, in some embodiments. Similarly, the optical second communication device 104 of the communication system 100 of FIG. 1 is different from the receiver device 250, in some embodiments.

The receiver 250 includes a line receiver device 252, a first set of flip-flops 254, a second set of flip-flops 256, a de-mapper 258, and a host SERDES transmitter device 260. The receiver 250 also includes a PLL 268 and a controller 264. The line receiver device 252 is configured to receive light signals from a communication link (e.g., the communication link 108) and to convert the light signals into electrical signals to generate a data stream 251. In an embodiment, the receiver device 250 includes a plurality of photodiodes configured convert signals received from a plurality of lanes of the communication link to electrical signals to generate the data stream 251. In an embodiment, the data stream comprises a data stream of width of M bits clocked at a line clock rate Cₗᵢₙₑ, where M is the number of lanes in the communication link and Cₗᵢₙₑ is a clock rate at which data is transmitted over each lane of the communication link. In an embodiment, Cₗᵢₙₑ is sufficiently high to support a maximum link speed of the communication link, such as 100 GHz. In this embodiment, Cₗᵢₙₑ is equal to or greater than the maximum link speed of the communication link divided by M. The receiver device 250 is configured to convert the data stream 251 to a data stream 253 of width N clocked at a clock rate Cₕₒₛₜ. In an embodiment, the clock rate Cₕₒₛₜ is proportional to the clock rate Cₗᵢₙₑ. For example, the clock rate Cₕₒₛₜ is equal to Cₗᵢₙₑ multiplied by the ratio M/N. In an embodiment, M is 32, Cₗᵢₙₑ is 3.52 GHZ, N is 128 bits, and the clock rate Cₕₒₛₜ is 880 MHZ. In other embodiments, other suitable data stream widths and/or other suitable clock rates are used.

The line receiver device 252 is configured to store the received bits of the data stream 251 in the set of flip-flops 254. The set of flip-flops 254 includes M flip-flops corresponding to the width of the data stream 251, in an embodiment. For example, the set of flip-flops 254 includes 32 flip-flops, in the illustrated embodiment. The PLL 268 is configured to receive a clock signal at the clock rate Cₗᵢₙₑ and to convert the clock signal to a clock signal at the clock rate Cₕₒₛₜ. For example, the PLL 268 is configured to generate the signal at the clock rate Cₕₒₛₜ that corresponds to the clock rate Cₗᵢₙₑ multiplied by M/N (e.g., 1/4 in the illustrated embodiment). In some embodiments, the clock signal received by the PLL 268 is noisy, and the PLL 268 is further configured to clean up the clock signal to generate a clean clock signal corresponding to the host clock rate Cₕₒₛₜ of the host device.

The receiver device 250 is configured to transfer bits saved in the set of flip-flops 254 to the set of flip-flops 256 during every clock cycle of the Cₗᵢₙₑ clock. The second set of flip-flops 256 includes N flip-flops corresponding to the width of the data stream 253, in an embodiment. For example, the second set of flip-flops 256 includes 128 bits, in the illustrated embodiment. The second set of flip-flops 256 is thus configured to accumulate N bits transferred from the set of flip-flops 256, in an embodiment. The controller 264 is configured to control the set of flip-flops 256 to output N bits every clock cycle of the clock Cₕₒₛₜ. The data stream of width N output from the set of flip-flops 256 is provided to the de-mapper 258. The de-mapper 258 de-interleaves the bits to reverse the interleaving performed by the re-mapper 206 of the transmitter device 200. The de-interleaved data stream is provided to the host SERDES transmitter 260, which, in turn, outputs the data stream for serialization of a SERDES of the host device, in an embodiment.

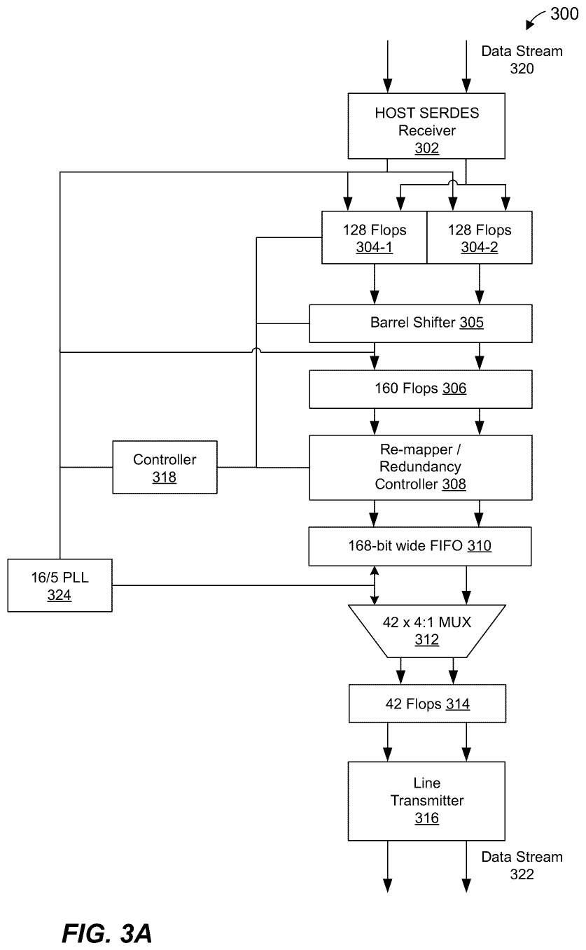

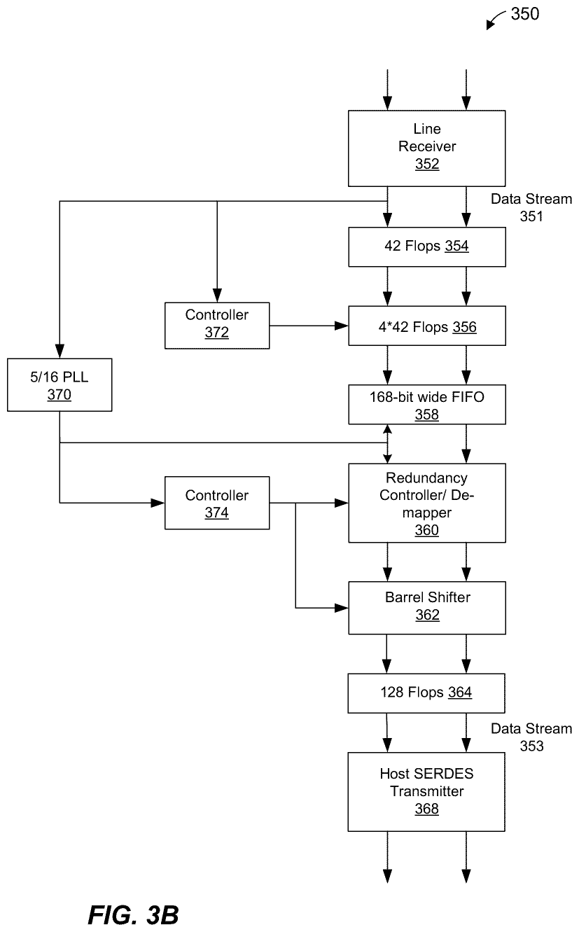

FIG. 3A is a block diagram of a portion of an example transmitter device 300 used in the system of FIG. 1, according to another embodiment. The transmitter device 300 corresponds to, or is included in, the optical first communication device 102 of the communication system 100 of FIG. 1, and for illustrative purposes the transmitter device 300 is described with reference to FIG. 1. However, the transmitter device 300 is used in communication systems different from the communication system of FIG. 1, in some embodiments. Similarly, the optical first communication device 102 of the communication system 100 of FIG. 1 is different from the transmitter device 300, in some embodiments.

The transmitter device 300 is similar to the transmitter device 200 of FIG. 2A and includes like-numbered elements with the transmitter device 200 of FIG. 2A. The transmitter device 300 is configured transmit data over a greater number of lanes of the communication link as compared to the transmitter device 200 of FIG. 2A, the greater number of lanes accommodating a wider data width and/or including additional redundancy lanes, in an embodiment. The transmitter device 300 includes a host SERDES receiver device 302 corresponding to the host SERDES receiver device 202 of FIG. 2A, in an embodiment. The transmitter device 300 also includes a first set of flip-flops 304, a barrel shifter 305, a re-mapper 306, a second set of flip-flops 306, a re-mapper/redundancy controller 308, a FIFO 310, a plurality of multiplexers 312, a fourth set of flip-flops 314, and a line transmitter 316. The transmitter device 300 also includes a PLL 324 and a controller 318. In an embodiment, the host SERDES receiver device 302 is configured to receive the data stream 320 of width N clocked at the clock rate Cₕₒₛₜ as discussed above with reference to FIG. 2A. In the embodiment illustrated in FIG. 3A, N is 128 bits and the clock rate Cₕₒₛₜ is 880 MHz. In an embodiment, the data stream 220 received by the SERDES receiver block 202 is an encoded data stream, encoded according to a block code that includes a plurality of symbols forming a codeword of the block code. For example, the data stream 220 is encoded by the Ethernet RS (544, 514) code.

The transmitter device 300 is configured to gearbox the received data stream 220 to a data stream 222 of width M clocked at a clock rate Cₗᵢₙₑ that is proportional to the clock rate Cₕₒₛₜ. The data stream of width M is transmitted over M data lanes in the optical communication link 108, in an embodiment. The width M is designed to include a sufficient number of data lanes to ensure that entire symbols of the code used to encode the data stream 220, in an embodiment. For example, the width M is 40, in an embodiment. Forty data lanes is sufficient to ensure that each symbol of the Ethernet RS (544, 514) code can be mapped onto a single data lane. The transmitter device 300 is configured to gearbox the data stream 220 of width of 128 bits to a data stream of width of 160 bits, and then gearbox the data stream of width of 160 bits to a data stream of width of 40 bits clocked at a clock rate Cₗᵢₙₑ that is equal to the clock rate Cₕₒₛₜ multiplied by 16/5, in the illustrated embodiment. The first set of flip-flops 304, the barrel shifter 305, the second set of flip-flops 306, the re-mapper/redundancy controller 308, the FIFO 310, the plurality of multiplexers 312, the fourth set of flip-flops 314, the PLL 324 and the controller 318 are configured to implement the gearbox functionality of the transmitter device 300, in an embodiment.

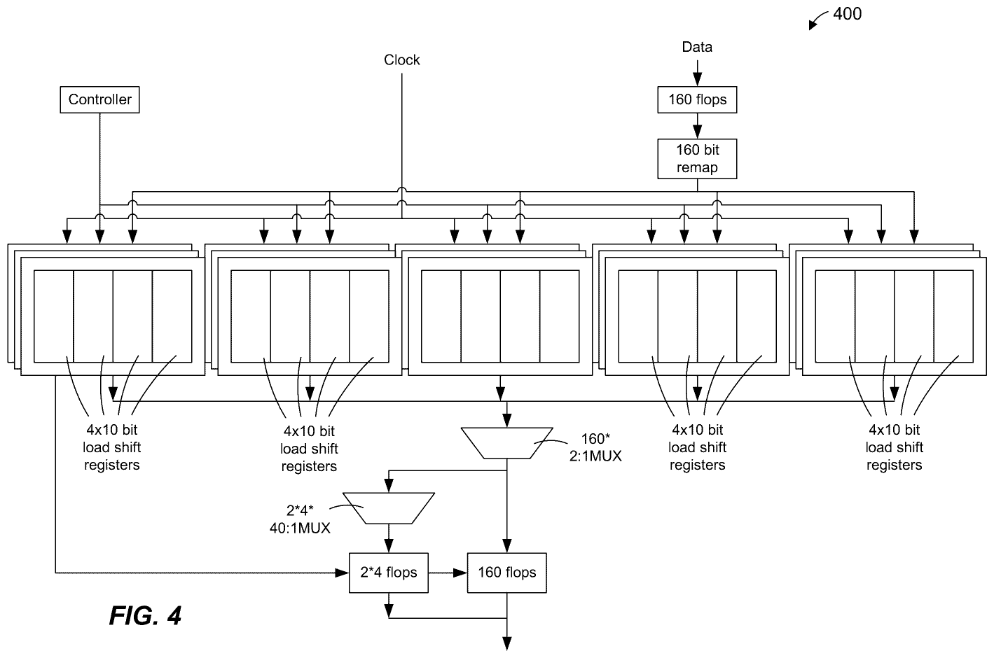

The host SERDES receiver device is configured to store the data stream 220 of width 128 bits received during consecutive clock cycles in respective sub-sets of flip-flops 304-1, 304-2 of the first set of flip-flops 304, in an embodiment. The barrel shifter 305 is configured to read out subsets of bits from the flip-flops 304-1, 304-2 in chucks of 160 bits and to store the 160 bits in the second set of flip-flops 306. The re-mapper/redundancy controller 308 is configured to remap the 160 bits such that entire symbols of the code used to encode the data stream 220 are transmitted over same data lanes and to add redundancy bits for transmission over the redundancy lanes, in an embodiment. Referring briefly to FIG. 4, a circuit 400 used to accumulate and read out the 160 bits is illustrated, according to an embodiment. The circuit 400 includes two stage 402 of serial shift registers 404, each set including five serial shift registers 404. The five sets of shift registers 404 provide storage of 80 bits. Accordingly, the stage 402 of serial shift registers 404 guarantee 160 bits. The circuit 400 thus allows accumulation and read out of 160 bits at a relatively small latency, in an embodiment. Referring again to FIG. 3A, in an embodiment, the re-mapper/redundancy controller 308 is configured to add eight redundancy bits to the 160 bits, where the 8 redundancy bits are copies of bits that are mapped onto a faulty data lane and are to be transferred to a redundant lane. The re-mapped bits with the added redundancy bits store in the FIFO 310 which includes 168 flip-flops, in the illustrated embodiment.

The PLL 324 is configured to receive a clock signal corresponding to the clock rate Cₕₒₛₜ from the host SERDES device and to derive a clock signal corresponding to the line clock rate Cₗᵢₙₑ that is proportional to the clock rate Cₕₒₛₜ of the host device. In an embodiment, the clock rate Cₗᵢₙₑ is obtained from the clock rate Cₕₒₛₜ by multiplying Cₕₒₛₜ by a factor of N/M (e.g., 16/5 in the illustrated embodiment). Accordingly, the PLL 324 is configured to generate a clock signal that is a multiple of the clock signal from the host SERDES device by a factor of 16/5, in the illustrated embodiment. In some embodiments, the clock signal received by the PLL 324 is noisy, and the PLL 324 is further configured to clean up the clock signal to generate a clean clock signal corresponding to the line clock rate Cₗᵢₙₑ.

The set of multiplexers 312 includes 42 4:1 multiplexers, in the illustrated embodiments. The controller 318 is configured to control the third set of flip-flops 310 to output the remapped bits and the additional bits added for redundancy by the re-mapper/redundancy controller 308 to the set of multiplexers 312. The multiplexers 312 are controlled by the controller 318 at the clock rate that is derived from the clock signal from the host SERDES by the PLL 324. Each of the multiplexers 312 corresponds to a lane and is configured to transfer a bit at the input to the multiplexers 312 onto the lane in every clock cycle under the control of the controller 318. The outputs of the multiplexers 312 are stored in the fourth set of flip-flops 314. The set of flip-flops 210 includes 42 flip-flops, in the illustrated embodiment. The fourth set of flip-flops 210 is controlled by the controller 318 to output 42 signals per clock cycle of the controller 318. The 42 signals drive respective LEDs of the transmitter device 300. The LEDs thus convert the signals into light signals and output the light signals into 32 lanes of the communication link 108 for transmission to the second communication device 104, in an embodiment.

FIG. 3B is a block diagram of an example receiver 350 configured to receive signals transmitted by the transmitter 300 of FIG. 3A, according to an embodiment. The receiver device 350 corresponds to, or is included in, the optical second communication device 104 of the communication system 100 of FIG. 1, and for illustrative purposes the receiver device 250 is described with reference to FIG. 1. However, the receiver device 350 is used in communication systems different from the communication system of FIG. 1, in some embodiments. Similarly, the optical second communication device 104 of the communication system 100 of FIG. 1 is different from the receiver device 350, in some embodiments.

The receiver 350 includes a line receiver device 352, a first set of flip-flops 354, a second set of flip-flops 356, a FIFO 358, a redundancy controller/de-mapper 360, a barrel shifter 362, a third set of flip-flops 364, and a host SERDES transmitter 368. The receiver 350 also includes a PLL 370, a first controller 372, and a second controller 374. The line receiver device 352 is configured to receive light signals from the optical communication link 108 and to convert the light signals into electrical signals to generate a data stream 351. In an embodiment, the receiver device 350 includes a plurality of photodiodes configured convert signals received from a plurality of lanes of the optical communication link 108 to electrical signals to generate the data stream 351. In an embodiment, the data stream 351 comprises a data stream of width of M bits clocked at a line clock rate Cₗᵢₙₑ, where M corresponds to the number of data lanes in the optical communication link 108 and Cₗᵢₙₑ is a clock rate at which data is transmitted over each lane of the optical communication link 108. The receiver device 350 is configured to convert the data stream 351 to a data stream 353 of width N clocked at a clock rate Cₕₒₛₜ. In an embodiment, the clock rate Cₕₒₛₜ is proportional to the clock rate Cₗᵢₙₑ. For example, the clock rate Cₕₒₛₜ is equal to Cₗᵢₙₑ multiplied by the ratio M/N. In an embodiment, M is 40, Cₗᵢₙₑ is 2.816 GHZ, N is 128 bits, and the clock rate Cₕₒₛₜ is 880 MHz. In other embodiments, other suitable data stream widths and/or other suitable clock rates are used.

The line receiver device 352 is configured to store the received bits of the data stream 351 in the first set of flip-flops 354. The first set of flip-flops 354 includes M flip-flops corresponding to the width of the data stream 351 and additional R flip-flops corresponding to the redundant lanes in the optical communication link 108, in an embodiment. For example, the first set of flip-flops 354 includes 42 flip-flops, including 40 flip-flops correspond to the width of the data stream 251 and additional two flip-flops corresponding to two redundant lanes in the optical communication link 108, in the illustrated embodiment. The PLL 370 is configured to receive a clock signal at the clock rate Cₗᵢₙₑ and to convert the clock signal to a clock signal at the clock rate Cₕₒₛₜ. For example, the PLL 370 is configured to generate the signal at the clock rate Cₕₒₛₜ that corresponds to the clock rate Cₗᵢₙₑ multiplied by M/N (e.g., 5/16 in the illustrated embodiment). In some embodiments, the clock signal received by the PLL 370 is noisy, and the PLL 370 is further configured to clean up the clock signal to generate a clean clock signal corresponding to the host clock rate Cₕₒₛₜ of the host device

The receiver device 350 is configured to transfer bits saved in the first set of flip-flops 354 to the second set of flip-flops 356 during every clock cycle of the Cₗᵢₙₑ clock for four consecutive clock cycles, in an embodiment. The second set of flip-flops 356 includes 4*M flip-flops corresponding to the width of the data stream 353 and additional redundancy bits, in an embodiment. For example, the second set of flip-flops 356 includes 168 bits, in the illustrated embodiment. The second set of flip-flops 356 is thus configured to accumulate 4*M bits and additional redundancy bits transferred from the second set of flip-flops 356, in an embodiment. The controller 372 is configured to control the set of flip-flops 356 to output 4*M and additional redundancy bits every clock cycle of the clock Cₗᵢₙₑ. The data stream of width 4*M and additional redundancy bits output from the set of flip-flops 356 is accumulated in the FIFO 358 and is provided to the redundancy controller and de-mapper 360. The redundancy controller and de-mapper 360 selects appropriate lanes, including data lanes and/or redundancy lanes, and de-interleaves the bits to reverse the interleaving performed by the re-mapper 308 of the transmitter device 300. The de-interleaved data stream is stored in the third set of flip-flops 364. The controller 374, operating at the clock rate Cₕₒₛₜ, controls the third set of flip-flops 364 to output 4*M bits every clock cycle, which are then read out by the barrel shifter in chunks of N bits (e.g., 128 bits in the illustrated embodiment) to generate the data stream 253. The data stream 253 is then transmitted to a host SERDES device by the host SERDES transmitter 368, in an embodiment.

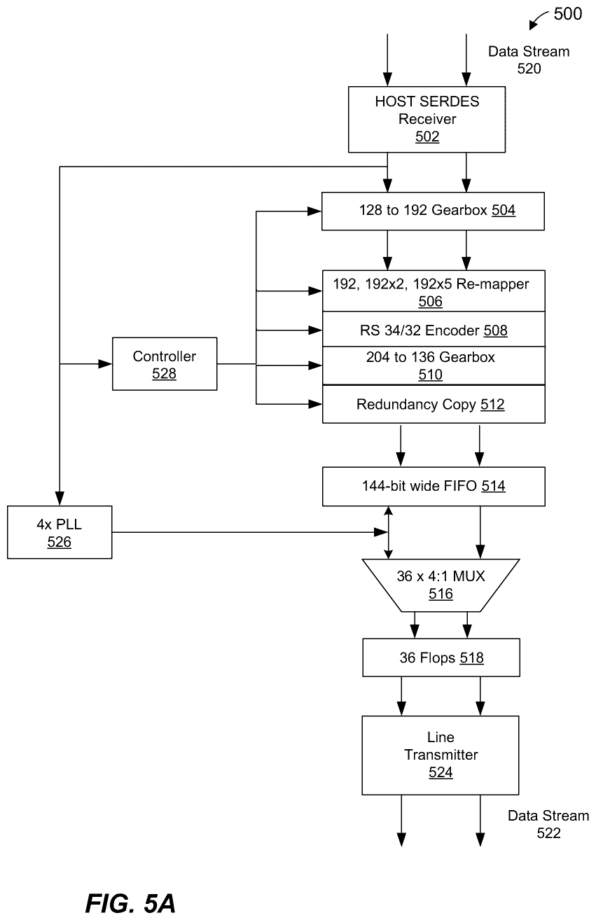

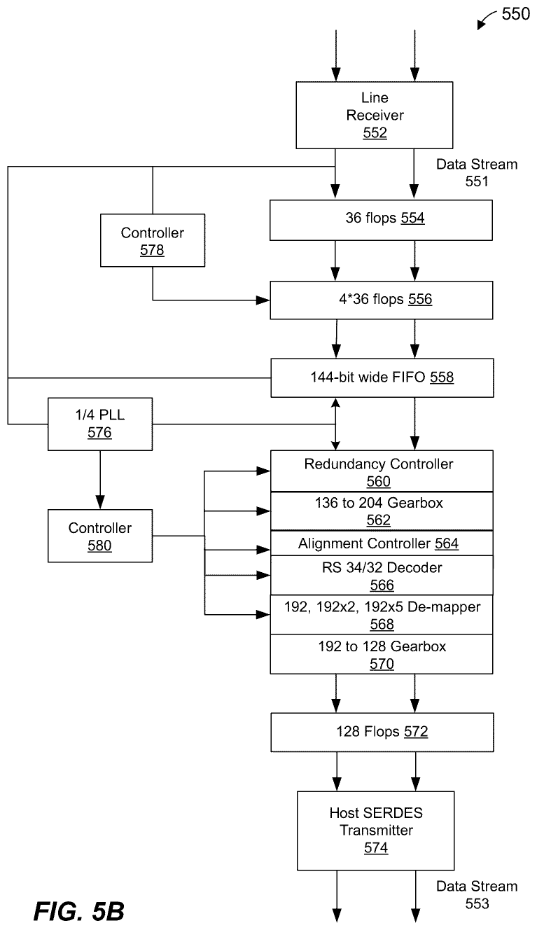

FIG. 5A is a block diagram of a portion of an example transmitter device 500 used in the system of FIG. 1, according to another embodiment. The transmitter device 500 corresponds to, or is included in, the optical first communication device 102 of the communication system 100 of FIG. 1, and for illustrative purposes the transmitter device 500 is described with reference to FIG. 1. However, the transmitter device 500 is used in communication systems different from the communication system of FIG. 1, in some embodiments. Similarly, the optical first communication device 102 of the communication system 100 of FIG. 1 is different from the transmitter device 300, in some embodiments.

The transmitter device 500 is similar to the transmitter device 200 of FIG. 2A and includes like-numbered elements with the transmitter device 200 of FIG. 2A. The transmitter device 500 is configured transmit data over a greater number of lanes of the communication link 108 as compared to the transmitter device 200 of FIG. 2A, the greater number of lanes including additional FEC lanes configured to accommodate additional encoding performed by the transmitter device 500 and/or including additional redundancy lanes, in an embodiment. The transmitter device 500 includes a host SERDES receiver device 502 corresponding to the host SERDES receiver device 202 of FIG. 2A, in an embodiment. The transmitter device 500 also includes a first gearbox 504, a re-mapper 506, an encoder 508, a second gearbox 510, a redundancy copy generator 512, a FIFO 514, a set of multiplexers 516, a set of flip-flops 518, and a line transmitter 524. The transmitter device 500 also includes a PLL 526 and a controller 528. In an embodiment, the host SERDES receiver device 502 is configured to receive a data stream 520 of width N clocked at the clock rate Cₕₒₛₜ. In the embodiment illustrated in FIG. 5A, N is 128 bits and the clock rate Cₕₒₛₜ is 880 MHz. In an embodiment, the data stream 520 received by the SERDES receiver block 502 is an encoded data stream, encoded according to a block code that includes a plurality of symbols forming a codeword of the block code. For example, the data stream 520 is encoded by the Ethernet RS (544, 514) code.

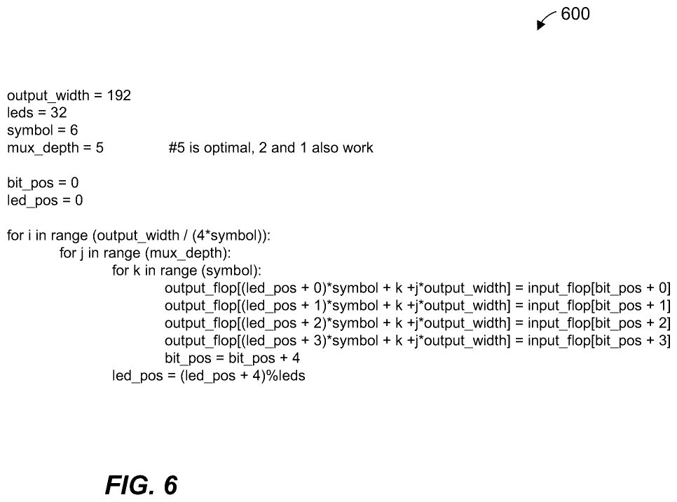

The gearbox 504 is configured to gearbox the received data stream 520 of width 128 bits to a data stream 522 of width 192 bits clocked at a clock rate Cₕₒₛₜ, in the illustrated embodiment. The 192 bits are provided to the re-mapper 506 configured to re-map the bits to provide a better distribution of symbols of the RS (544, 514) code among data lanes, to maximize mapping of respective data symbols to same data lanes, to in an embodiment. Referring briefly to FIG. 6, in an embodiment, the re-mapper 506 is configured to remap the bits according to a re-mapping function 600 illustrated in FIG. 6. In other embodiments, other suitable remapping functions are used.

Referring again to FIG. 5A, the data stream remapped by the re-mapper 506 is further encoded by the encoder 508. In an embodiment, the encoder 508 utilizes a RS (34, 32) code with a symbol size of six or more bits. In an embodiment, the transmitter device 500 is configured to transmit the data stream encoded by the encoder 508 such that each symbol of the RS (34, 32) code of size six or more bits is transmitted on a same lane of the optical communication link 108. In this embodiment, the RS (34, 32) code allow for correction of a single symbol out of the 34 symbols, thereby allowing a receiver device to i) correct a single bit error in any given clock cycle, ii) correct a burst error down a single lane (e.g., over multiple clock cycles) and/or ii) repair a dead lane. In other embodiments, the encoder 508 utilizes other suitable encoding schemes.

The PLL 526 is configured to receive a clock signal at the clock rate Cₕₒₛₜ from the host SERDES device and to derive a clock signal at the line clock rate Cₗᵢₙₑ that is proportional to the clock rate Cₕₒₛₜ of the host device. In an embodiment, the clock rate Cₗᵢₙₑ is obtained from the clock rate Cₕₒₛₜ by multiplying Cₕₒₛₜ by a factor of N/M (e.g., 4 in the illustrated embodiment). Accordingly, the PLL 526 is configured to generate a clock signal at the clock rate Cₗᵢₙₑ that is a multiple of the clock signal from the host SERDES device by a factor of 4, in the illustrated embodiment. In some embodiments, the clock signal received by the PLL 526 is noisy, and the PLL 526 is further configured to clean up the clock signal to generate a clean clock signal corresponding to the line clock rate Cₗᵢₙₑ.

The data stream encoded by the encoder 508 is gearboxed from 204 bits to 136 bits by the second gearbox 510. The redundancy copy generator 512 then adds redundancy bits for transmission via two redundant lanes of the optical communication link 108, thus generating a data stream of width 144 bits, in the illustrated embodiment. The 144 bits are stored in the FIFO 514 and are read out from the FIFO 514 at the Cₗᵢₙₑ clock rate under the control of the controller 528, in an embodiment. The bits read out from the FIFO 514 are provided to the set of multiplexers 516. The set of multiplexers 516 includes 36 4:1 multiplexers 516, each multiplexers 516 configured to, in each clock cycle of the clock rate Cₗᵢₙₑ, output a bit for transmission via a respective lane in the optical communication link 108. The outputs of the multiplexers 516 are stored in the fourth set of flip-flops 518. The set of flip-flops 518 includes 36 flip-flops, in the illustrated embodiment. The set of flip-flops 518 outputs 36 signals per clock cycle of the clock rate Cₗᵢₙₑ. The 36 signals drive respective LEDs of the transmitter device 500. The LEDs thus convert the signals into light signals and output the light signals into 36 lanes of the optical communication link 108 for transmission to the second communication device 104, in an embodiment.

FIG. 5B is a block diagram of an example receiver 550 configured to receive signals transmitted by the transmitter 500 of FIG. 5A, according to an embodiment. The receiver device 550 corresponds to, or is included in, the second communication device 104 of the communication system 100 of FIG. 1, and for illustrative purposes the receiver device 550 is described with reference to FIG. 1. However, the receiver device 550 is used in communication systems different from the communication system of FIG. 1, in some embodiments. Similarly, the second communication device 104 of the communication system 100 of FIG. 1 is different from the receiver device 550, in some embodiments.

The receiver 550 includes a line receiver device 552, a first set of flip-flops 554, a second set of flip-flops 556, a FIFO 558, a redundancy controller 560, a first gearbox 562, an alignment controller 564, a decoder 566, a re-mapper 568, a second gearbox 570, a second set of flip-flops 572, and a host SERDES transmitter 574. The receiver 550 also includes a PLL 576, a first controller 578, and a second controller 580. The line receiver device 552 is configured to receive light signals from the optical communication link 108 and to convert the light signals into electrical signals to generate a data stream 551. In an embodiment, the receiver device 550 includes a plurality of photodiodes configured convert signals received from a plurality of lanes of the optical communication link 108 to electrical signals to generate the data stream 551. In an embodiment, the data stream 551 includes a data stream of width of M bits clocked at a line clock rate Cₗᵢₙₑ, where M corresponds to the number of data lanes in the optical communication link 108 and Cₗᵢₙₑ is a clock rate at which data is transmitted over each lane of the optical communication link 108. The receiver device 550 is configured to convert the data stream 551 to a data stream 553 of width N clocked at a clock rate Cₕₒₛₜ. In an embodiment, the clock rate Cₕₒₛₜ is proportional to the clock rate Cₗᵢₙₑ. For example, the clock rate Cₕₒₛₜ is equal to Cₗᵢₙₑ multiplied by the ratio M/N. In an embodiment, M is 32, Cₗᵢₙₑ is 3.52 GHZ, N is 128 bits, and the clock rate Cₕₒₛₜ is 880 MHz. In other embodiments, other suitable data stream widths and/or other suitable clock rates are used. The data stream 551 also includes F (e.g., 2) bits added by the encoder 508 and R (e.g., 2) redundancy bits. Accordingly, the width of the data stream 551 is M+F+R, which is equal to 36 bits, in the illustrated embodiment.

The line receiver device 552 is configured to store the received bits of the data stream 551 in the first set of flip-flops 554. The first set of flip-flops 554 includes M+F+R (e.g., 36) flip-flops corresponding to the width of the data stream 551, in an embodiment. The PLL 576 is configured to receive a clock signal at the clock rate Cₗᵢₙₑ and to convert the clock signal to a clock signal at the clock rate Cₕₒₛₜ. For example, the PLL 576 is configured to generate the signal at the clock rate Cₕₒₛₜ that corresponds to the clock rate Cₗᵢₙₑ multiplied by M/N (e.g., 1/4 in the illustrated embodiment). In some embodiments, the clock signal received by the PLL 576 is noisy, and the PLL 576 is further configured to clean up the clock signal to generate a clean clock signal corresponding to the host clock rate Cₕₒₛₜ of the host device

The receiver device 550 is configured to transfer bits saved in the first set of flip-flops 554 to the second set of flip-flops 556 during every clock cycle of the Cₗᵢₙₑ clock for four consecutive clock cycles, in an embodiment. The second set of flip-flops 556 includes 4*(M+F+R) flip-flops corresponding to the width of the data stream 553, in an embodiment. For example, the second set of flip-flops 556 includes 4*36 bits, in the illustrated embodiment. The second set of flip-flops 556 is thus configured to accumulate 4*(M+F+R) (e.g., 4*36) bits and additional redundancy bits transferred from the second set of flip-flops 556, in an embodiment. The controller 578 is configured to control the set of flip-flops 556 to output 4*(M+F+R) bits every clock cycle of the clock Cₗᵢₙₑ. The data stream of width 4*(M+F+R) output from the set of flip-flops 556 is accumulated in the FIFO 558 and is provided to the redundancy controller 560. The redundancy controller 560 selects appropriate lanes, including data lanes and/or redundancy lanes, in an embodiment. The data from the selected lanes is then gearboxed by the first gearbox 562, which gearboxes 136 bits to 204 bits, in the illustrated embodiment. The alignment controller 564 is configured to implement as alignment scheme to synchronize with the transmitter device 500 on the incoming data during link bring-up to eliminate boot to boot latency variation, in an embodiment. The decoder 566 decodes the data based on the coding scheme (e.g., the RS (34, 32) coding scheme) of the encoder 508 of the transmitter device 500. The de-mapper 568 reorders the bits to restore the order of the bits of the Ethernet RS (544, 514) code, in an embodiment. The second gearbox the gearboxes 192 de-mapped bits to 128 bits, in the illustrated embodiment. The gearboxed 128-bit wide data stream is stored in the third set of flip-flops 572. The controller 580, operating at the clock rate Cₕₒₛₜ, controls the third set of flip-flops 572 to output 4*M bits every clock cycle, which are then read out by the barrel shifter in chunks of N bits (e.g., 128 bits in the illustrated embodiment) to generate the data stream 553. The data stream 553 is then transmitted to a host SERDES device by the host SERDES transmitter 574, in an embodiment.

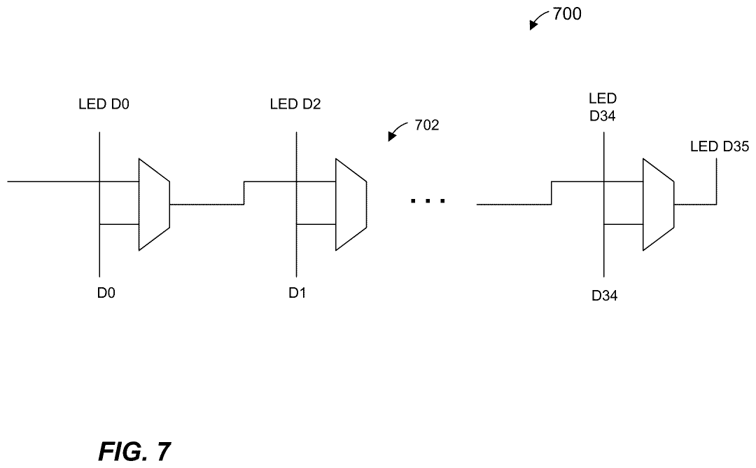

Referring briefly to FIG. 7, a block diagram of an example redundancy controller 700 is illustrated, according to an embodiment. The redundancy controller 700 is used as the redundancy controllers described above with reference to FIGS. 1, 2A-B, 3A-B, and 5A-B, in various embodiments. The redundant controller 700 includes 2*M:2 input multiplexers 702 (Dn, MUXn-1) arranged in series, with output of the final multiplexer 702 in the series controlling the redundant lane LED, in an embodiment. In operation, the configuration signal (CfgReg) is provided to the Dn input on the first multiplexer 702 in the series. Although only one chain of multiplexers 702 is illustrated in FIG. 7, it is noted that the redundancy controller 700 includes a chain of multiplexers 702 for each redundant bit, in an embodiment. In this redundancy controller architecture, LED outputs other than the redundant LEDs are not switched. Accordingly, the transfer of a faulty lane to a redundant lane does not affect the remainder of the communication link. Due to the delay through the serially connected multiplexers 702, pipelining and closing timing in the redundancy controller 700 is difficult, in some embodiments.

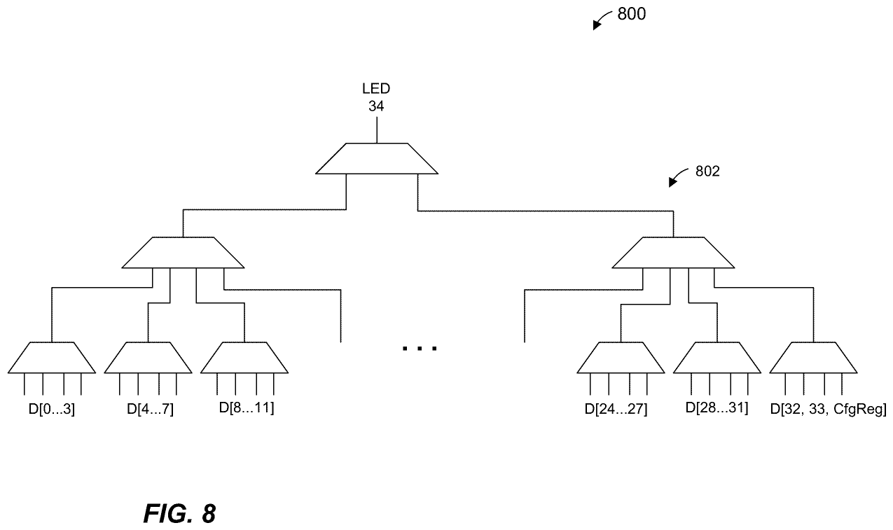

FIG. 8 is a block diagram of an example redundancy controller 800, according to another embodiment. The redundancy controller 800 is used as the redundancy controllers described above with reference to FIGS. 1, 2A-B, 3A-B, and 5A-B, in various embodiments. The redundancy controller 800 includes 2*(9+2+1) 4 input multiplexers 802 arranged in three layers, with output of the final output multiplexer 802 controlling the redundant LED, in an embodiment. The three layers of multiplexers 802 implement a 34:1 multiplexer, in the illustrated embodiment. In operation, the configuration signal (CfgReg) is provided to the final multiplexer 802 in the first layer, in the illustrated embodiment. Although only one three-layer arrangement of multiplexers 802 is illustrated in FIG. 8, it is noted that the redundancy controller 800 includes such three-layer arrangement of multiplexers 802 for each redundant bit, in an embodiment. Similar to the architecture of redundancy controller 700 of FIG. 7, LED outputs other than the redundant LED are not switched in the architecture of the redundancy controller 800 of FIG. 8. Accordingly, the transfer of a faulty lane to a redundant lane does not affect the remainder of the communication link. In the architecture of the redundancy controller 800 of FIG. 8, pipelining and closing of timing is easier to achieve as compared to the redundancy controller 800 of FIG. 8, in at least some embodiments.

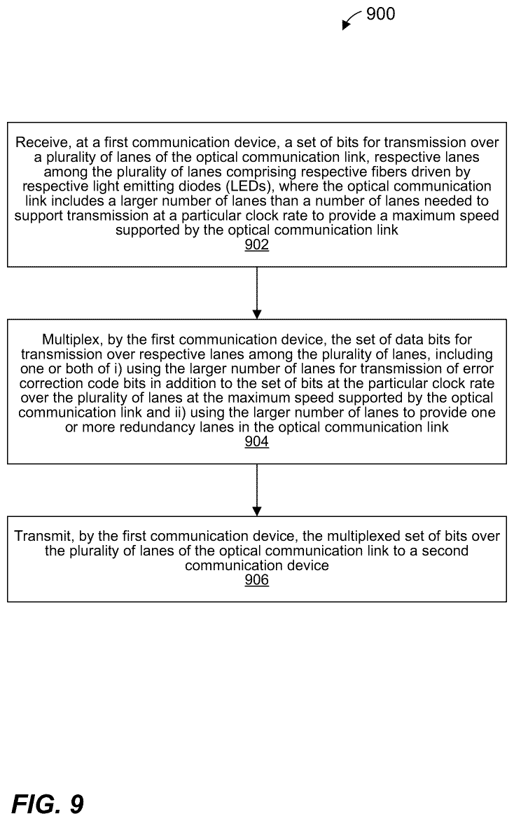

FIG. 9 is a flow chart of an example method 900 for communicating over an optical communication link, according to an embodiment. In an embodiment, the method 900 is implemented by the first communication device 102 of FIG. 1, and the method 900 is described with reference to FIG. 1 for case of explanation. In other embodiments, the method 900 is implemented by a suitable network device different from the first communication device 102 of FIG. 1 and/or in a system different from the system 100 of FIG. 1.

At a block 902, a set of bits is received by the first communication device. The set of bits is for transmission over a plurality of lanes of the optical communication link to a second communication device. In an embodiment, the respective lanes among the plurality of lanes comprise respective fibers driven by respective light emitting diodes (LEDs). In an embodiment, the optical communication link includes a larger number of lanes than a number of lanes needed to support transmission at a particular clock rate to provide a maximum speed supported by the optical communication link.

At a block 904, bits of the set of data bits are multiplexed for transmission over respective lanes among the plurality of lanes of the optical communication link. In an embodiment, transmission over respective lanes among the plurality of lanes of the optical communication link includes one or both of i) using the larger number of lanes for transmission of error correction code bits in addition to the set of bits at the particular clock rate over the plurality of lanes at the maximum speed supported by the optical communication link and ii) using the larger number of lanes to provide one or more redundancy lanes in the optical communication link. As discussed above, in various embodiments, the one or both of i) using the larger number of lanes for transmission of error correction code bits in addition to the set of bits at the particular clock rate over the plurality of lanes at the maximum speed supported by the optical communication link and ii) using the larger number of lanes to provide one or more redundancy lanes in the optical communication link improves resiliency of the communication link and/or allows for implementation of hitless link recovery without having to re-initialize the communication link, in at least some embodiments.

At a block 906, the multiplexed set of bits is transmitted to the second communication device over the plurality of lanes of the optical communication link to a second communication device.

Embodiment 1: A method for communication over an optical communication link, the method comprising: receiving, at a first communication device, a set of bits for transmission over a plurality of lanes of the optical communication link, respective lanes among the plurality of lanes comprising respective fibers driven by respective light emitting diodes (LEDs), wherein the optical communication link includes a larger number of lanes than a number of lanes needed to support transmission at a particular clock rate to provide a maximum speed supported by the optical communication link; multiplexing, by the first communication device, the set of data bits for transmission over respective lanes among the plurality of lanes, including one or both of i) using the larger number of lanes for transmission of error correction code bits in addition to the set of bits at the particular clock rate over the plurality of lanes at the maximum speed supported by the optical communication link and ii) using the larger number of lanes to provide one or more redundancy lanes in the optical communication link; and transmitting, by the first communication device, the multiplexed set of bits over the plurality of lanes of the optical communication link to a second communication device.

Embodiment 2: The method of embodiment 1, wherein: the plurality of lanes includes one or more redundancy lanes; and the method further comprises determining, by the first communication device, a fault on a first lane among the plurality of lanes, the first lane being driven by a first LED, and in response to determining the fault on the first lane among the plurality of lanes, transferring, by the first communication device, transmission from the lane on which the fault was detected to a redundancy lane among the one or more redundancy lanes, the redundancy lane being driven by a second LED different from the first LED.

Embodiment 3: The method of embodiment 2, wherein determining the fault on the first lane includes receiving an indication of the fault on the first lane from the second communication device over a sideband channel between the first communication device and the second communication device.

Embodiment 4: The method of embodiment 3, wherein determining the fault on the first lane includes receiving the indication of the fault on the first lane in response to the second communication device detecting that a bit stream received from the first lane is stuck at bit value of zero or one for a predetermined period of time.

Embodiment 5: The method of embodiment any of embodiments 2-5, wherein transferring transmission from the first lane on which the fault was detected to the redundancy lane includes: generating a copy of data mapped onto the first lane on which the fault was detected; and multiplexing the copy of data onto the redundancy lane among the one or more redundancy lanes without shifting data from other lanes among the plurality of lanes.

Embodiment 6: The method of any of embodiments 1-5, wherein: receiving the set of bits includes receiving an encoded data stream, wherein the encoded data stream is encoded by a first Reed Solomon code having a first code word length; and the method further includes encoding, by the first communication device, the encoded data stream using a second Reed Solomon code having a second code word length different from the first code word length.

Embodiment 7: The method of embodiment 6, wherein: receiving the set of bits includes receiving an encoded data stream, wherein the encoded data stream is encoded by the first Reed Solomon code having a first symbol size; and the method further includes encoding, by the first communication device, the encoded data stream using the second Reed Solomon code having a second symbol size different from the first symbol size.

Embodiment 8: The method of embodiment 7, further comprising, prior to encoding the set of data bits using the second Reed Solomon code, re-mapping the set of data bits to maximize mapping of bits corresponding to a same codeword of the first Reed Solomon code onto a same lane among the plurality of lanes of the optical communication link.

Embodiment 9: The method of any of embodiments 1-8, wherein: receiving the set of bits comprises receiving the set of bits at a first clock rate; and transmitting the multiplexed set of bits over the plurality of lanes comprises transmitting the multiplexed set of bits at the particular clock rate, wherein the particular clock rate is an integer multiple of the first clock rate.

Embodiment 10: The method of any of embodiments 1-9, wherein transmitting the multiplexed set of bits over the plurality of lanes of the optical communication link includes: modulating respective light emitting diodes (LEDs) to generate respective light signals based on respective bits among the set of bits; and transmitting the respective light signals over respective lanes among the plurality of lanes of the optical communication link.

Embodiment 11: A first communication device, comprising a transceiver including: a receiver configured to receive a set of bits for transmission over a plurality of lanes of an optical communication link, respective lanes among the plurality of lanes comprising respective fibers driven by respective light emitting diodes (LEDs), wherein the optical communication link includes a larger number of lanes than a number of lanes needed to support transmission at a particular clock rate to provide a maximum speed supported by the optical communication link; one or more multiplexers configured to multiplex the set of data bits for transmission over respective lanes among the plurality of lanes, including one or both of i) using the larger number of lanes for transmission of error correction code bits in addition to the set of bits at the particular clock rate over the plurality of lanes at the maximum speed supported by the optical communication link and ii) using the larger number of lanes to provide one or more redundancy lanes in the optical communication link; and a transmitter configured to transmit the multiplexed set of bits over the plurality of lanes of the optical communication link to a second communication device.

Embodiment 12: The first communication device of embodiment 11, wherein: the plurality of lanes includes one or more redundancy lanes; and the transceiver further includes a redundancy controller configured to determine a fault on a first lane among the plurality of lanes, the first lane being driven by a first LED, and in response to determining the fault on the first lane among the plurality of lanes, transfer transmission from the lane on which the fault was detected to a redundancy lane among the one or more redundancy lanes, the redundancy lane being driven by a second LED different from the first LED.

Embodiment 13: The first communication device of embodiment 12, wherein the redundancy controller is configured to determine the fault on the first lane among the plurality of lanes at least by receiving an indication of the fault on the first lane from the second communication device over a sideband channel between the first communication device and the second communication device.

Embodiment 14: The first communication device of embodiment 13, wherein the redundancy controller is configured to determine the fault on the first lane at least by receiving the indication in response to the second communication device detecting that a bit stream received from the first lane is stuck at bit value of zero or bit value of one for a predetermined period of time.

Embodiment 15: The first communication device of any of embodiments 12-14, wherein the redundancy controller is configured to transfer transmission from the first lane on which the fault was detected to the redundancy lane at least by: generating a copy of data mapped onto the first lane on which the fault was detected; and multiplexing the copy of data onto the redundancy lane without shifting data from other lanes among the plurality of lanes.

Embodiment 15: The first communication device of any of embodiments 11-14, wherein: the set of bits received by the receiver is an encoded data stream, wherein the encoded data stream is encoded by a first Reed Solomon code having a first code word length; and the transceiver further includes an encoder configured to encode the encoded data stream using a second Reed Solomon code having a second code word length different from the first code word length.

Embodiment 16: The first communication device of embodiment 15, wherein: the encoded data stream is encoded by the first Reed Solomon code having a first symbol size; and the encoder is configured to encode the encoded data stream using the second Reed Solomon code having a second symbol size different from the first symbol size.

Embodiment 17: The first communication device of embodiment 16, wherein the transceiver further comprises a re-mapper configured to, prior to encoding the set of data bits using the second Reed Solomon code, re-map the set of data bits to maximize mapping of bits corresponding to a same codeword of the first Reed Solomon code onto a same lane among the plurality of lanes of the optical communication link.

Embodiment 19: The first communication device of any of embodiments 11-18, wherein: the receiver is configured to receive the set of bits at a first clock rate; and the transmitter is configured to transmit the multiplexed set of bits over the plurality of lanes at the particular clock rate, wherein the particular clock rate is an integer multiple of the first clock rate.

Embodiment 20: The first communication device of any of embodiments 11-19, wherein the transmitter is configured to transmit the multiplexed set of bits over the plurality of lanes of the optical communication link at least by: modulating respective light emitting diodes (LEDs) to generate respective light signals based on respective bits among the set of bits; and transmitting the respective light signals over respective lanes among the plurality of lanes of the optical communication link.

At least some of the various blocks, operations, and techniques described above may be implemented utilizing hardware, a processor executing firmware instructions, a processor executing software instructions, or any combination thereof. When implemented utilizing a processor executing software or firmware instructions, the software or firmware instructions may be stored in any computer readable memory coupled to the processor, such as a RAM, a ROM, a flash memory, etc. The software or firmware instructions may include machine readable instructions that, when executed by one or more processors, cause the one or more processors to perform various acts.

When implemented in hardware, the hardware may comprise one or more of discrete components, an integrated circuit, an application-specific integrated circuit (ASIC), a programmable logic device (PLD), etc.

While the present invention has been described with reference to specific examples, which are intended to be illustrative only and not to be limiting of the invention, changes, additions and/or deletions may be made to the disclosed embodiments without departing from the scope of the invention.

What is claimed is:

1. A method for communication over an optical communication link, the method comprising:
receiving, at a first communication device, a set of bits for transmission over a plurality of lanes of the optical communication link, respective lanes among the plurality of lanes comprising respective fibers driven by respective light emitting diodes (LEDs), wherein the optical communication link includes a larger number of lanes than a number of lanes needed to support transmission at a particular clock rate to provide a maximum speed supported by the optical communication link;
multiplexing, by the first communication device, the set of data bits for transmission over respective lanes among the plurality of lanes, including one or both of i) using the larger number of lanes for transmission of error correction code bits in addition to the set of bits at the particular clock rate over the plurality of lanes at the maximum speed supported by the optical communication link and ii) using the larger number of lanes to provide one or more redundancy lanes in the optical communication link; and
transmitting, by the first communication device, the multiplexed set of bits over the plurality of lanes of the optical communication link to a second communication device.

2. The method of claim 1, wherein:
the plurality of lanes includes one or more redundancy lanes; and
the method further comprises
determining, by the first communication device, a fault on a first lane among the plurality of lanes, the first lane being driven by a first LED, and
in response to determining the fault on the first lane among the plurality of lanes, transferring, by the first communication device, transmission from the lane on which the fault was detected to a redundancy lane among the one or more redundancy lanes, the redundancy lane being driven by a second LED different from the first LED.

3. The method of claim 2, wherein determining the fault on the first lane includes receiving an indication of the fault on the first lane from the second communication device over a sideband channel between the first communication device and the second communication device.

4. The method of claim 3, wherein determining the fault on the first lane includes receiving the indication of the fault on the first lane in response to the second communication device detecting that a bit stream received from the first lane is stuck at bit value of zero or one for a predetermined period of time.

5. The method of claim 2, wherein transferring transmission from the first lane on which the fault was detected to the redundancy lane includes:
generating a copy of data mapped onto the first lane on which the fault was detected; and
multiplexing the copy of data onto the redundancy lane among the one or more redundancy lanes without shifting data from other lanes among the plurality of lanes.

6. The method of claim 1, wherein:
receiving the set of bits includes receiving an encoded data stream, wherein the encoded data stream is encoded by a first Reed Solomon code having a first code word length; and
the method further includes encoding, by the first communication device, the encoded data stream using a second Reed Solomon code having a second code word length different from the first code word length.

7. The method of claim 6, wherein:
receiving the set of bits includes receiving an encoded data stream, wherein the encoded data stream is encoded by the first Reed Solomon code having a first symbol size; and
the method further includes encoding, by the first communication device, the encoded data stream using the second Reed Solomon code having a second symbol size different from the first symbol size.

8. The method of claim 7, further comprising, prior to encoding the set of data bits using the second Reed Solomon code, re-mapping the set of data bits to maximize mapping of bits corresponding to a same codeword of the first Reed Solomon code onto a same lane among the plurality of lanes of the optical communication link.

9. The method of claim 1, wherein:
receiving the set of bits comprises receiving the set of bits at a first clock rate; and
transmitting the multiplexed set of bits over the plurality of lanes comprises transmitting the multiplexed set of bits at the particular clock rate, wherein the particular clock rate is an integer multiple of the first clock rate.

10. The method of claim 1, wherein transmitting the multiplexed set of bits over the plurality of lanes of the optical communication link includes:
modulating respective light emitting diodes (LEDs) to generate respective light signals based on respective bits among the set of bits; and
transmitting the respective light signals over respective lanes among the plurality of lanes of the optical communication link.

11. A first communication device, comprising:
a transceiver, including:
a receiver configured to receive a set of bits for transmission over a plurality of lanes of an optical communication link, respective lanes among the plurality of lanes comprising respective fibers driven by respective light emitting diodes (LEDs), wherein the optical communication link includes a larger number of lanes than a number of lanes needed to support transmission at a particular clock rate to provide a maximum speed supported by the optical communication link,
one or more multiplexers configured to multiplex the set of data bits for transmission over respective lanes among the plurality of lanes, including one or both of i) using the larger number of lanes for transmission of error correction code bits in addition to the set of bits at the particular clock rate over the plurality of lanes at the maximum speed supported by the optical communication link and ii) using the larger number of lanes to provide one or more redundancy lanes in the optical communication link, and
a transmitter configured to transmit the multiplexed set of bits over the plurality of lanes of the optical communication link to a second communication device.

12. The first communication device of claim 11, wherein:
the plurality of lanes includes one or more redundancy lanes; and
the transceiver further includes a redundancy controller configured to
determine a fault on a first lane among the plurality of lanes, the first lane being driven by a first LED, and
in response to determining the fault on the first lane among the plurality of lanes, transfer transmission from the lane on which the fault was detected to a redundancy lane among the one or more redundancy lanes, the redundancy lane being driven by a second LED different from the first LED.

13. The first communication device of claim 12, wherein the redundancy controller is configured to determine the fault on the first lane among the plurality of lanes at least by receiving an indication of the fault on the first lane from the second communication device over a sideband channel between the first communication device and the second communication device.

14. The first communication device of claim 13, wherein the redundancy controller is configured to determine the fault on the first lane at least by receiving the indication in response to the second communication device detecting that a bit stream received from the first lane is stuck at bit value of zero or bit value of one for a predetermined period of time.

15. The first communication device of claim 12, wherein the redundancy controller is configured to transfer transmission from the first lane on which the fault was detected to the redundancy lane at least by:
generating a copy of data mapped onto the first lane on which the fault was detected; and
multiplexing the copy of data onto the redundancy lane without shifting data from other lanes among the plurality of lanes.

16. The first communication device of claim 11, wherein:
the set of bits received by the receiver is an encoded data stream, wherein the encoded data stream is encoded by a first Reed Solomon code having a first code word length; and
the transceiver further includes an encoder configured to encode the encoded data stream using a second Reed Solomon code having a second code word length different from the first code word length.

17. The first communication device of claim 16, wherein:
the encoded data stream is encoded by the first Reed Solomon code having a first symbol size; and
the encoder is configured to encode the encoded data stream using the second Reed Solomon code having a second symbol size different from the first symbol size.

18. The first communication device of claim 16, wherein the transceiver further comprises a re-mapper configured to, prior to encoding the set of data bits using the second Reed Solomon code, re-map the set of data bits to maximize mapping of bits corresponding to a same codeword of the first Reed Solomon code onto a same lane among the plurality of lanes of the optical communication link.

19. The first communication device of claim 11, wherein:
the receiver is configured to receive the set of bits at a first clock rate; and
the transmitter is configured to transmit the multiplexed set of bits over the plurality of lanes at the particular clock rate, wherein the particular clock rate is an integer multiple of the first clock rate.

20. The first communication device of claim 11, wherein the transmitter is configured to transmit the multiplexed set of bits over the plurality of lanes of the optical communication link at least by:
modulating respective light emitting diodes (LEDs) to generate respective light signals based on respective bits among the set of bits; and
transmitting the respective light signals over respective lanes among the plurality of lanes of the optical communication link.
